(19) United States
(12) Patent Application Publication
(10) Pub. No.: US 2026/0182001 A1
(43) Pub. Date: Jun. 25, 2026

(54) STRUCTURE AND METHOD FOR METAL GATE ISOLATION

(71) Applicant: Taiwan Semiconductor Manufacturing Company, Ltd., Hsinchu (TW)

(72) Inventors: Chia-Yeh Lu, Hsinchu City (TW); Liang-Chih Wang, Hsinchu County (TW); Shang-Shuo Huang, Kaohsiung City (TW); Chih-Chang Hung, Hsinchu City (TW)

(73) Assignee: Taiwan Semiconductor Manufacturing Company, Ltd., Hsinchu (TW)

(21) Appl. No.: 18/989,177

(22) Filed: Dec. 20, 2024

(51) Int. Cl. H10D 84/01; H01L 21/02; H01L 21/3213; H10D 30/00; H10D 84/83

(52) U.S. Cl. CPC H10D 84/0153; H10D 84/832; H10P 14/6336; H10P 50/267; H10D 30/501

(57) ABSTRACT

A method includes: providing a plurality of fins that extend vertically above a substrate and a contiguous gate structure that extends over the plurality of fins; forming an opening in the contiguous gate structure with a metal gate cut between a pair of fins, wherein forming the opening includes etching a partial opening to a current depth and performing an etching cycle including: depositing a protective layer on sidewalls of the partial opening; and extending, via etching, the partial opening a predetermined incremental depth below the current depth; and repeating the etching cycle for at least 10 cycles to achieve a desired gate cut length.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a partial top view of a semiconductor device during a stage of fabrication that illustrates isolation cuts that are made to gate structures, in accordance with some embodiments.

FIG. 1B is a partial top view of a semiconductor device during a stage of fabrication that illustrates dense cuts that are made to gate structures, in accordance with some embodiments.

FIG. 2A is a cross-sectional view of a semiconductor device during a stage of fabrication that illustrates cuts (isolation cuts or dense cuts) that are made to gate structures for a FinFET, in accordance with some embodiments.

FIG. 2B is a cross-sectional view of a semiconductor device during a stage of fabrication that illustrates cuts (isolation cuts or dense cuts) that are made to gate structures for a GAAFET, in accordance with some embodiments.

FIG. 3 is a flow chart depicting an example method of semiconductor fabrication including fabrication of multi-gate devices, in accordance with some embodiments.

FIGS. 4-5, 6A-6C, 7, 8A-8B, and 9-17, are cross-sectional diagrams that illustrate a semiconductor device or structure at various stages of fabrication, in accordance with some embodiments.

FIG. 18 is a flow diagram depicting an example cut metal gate process, in accordance with some embodiments.

FIGS. 19A-19H depict cross-sectional views of a semiconductor device at various stages of fabrication during performance of the cut metal gate process of FIG. 18, in accordance with some embodiments.

FIG. 20 is a flow diagram depicting an example method of cutting a contiguous metal gate structure, according to some embodiments.

FIGS. 21A-21I, depict cross-sectional views of a semiconductor device at various stages of fabrication during performance of the method of FIG. 20, according to some embodiments.

FIG. 22A is a diagram depicting a cross-sectional view of an example semiconductor structure after an opening has been formed through a gate structure, according to some embodiments.

FIG. 22B is a diagram depicting a cross-sectional view of an example semiconductor structure after a dielectric has been filled in an opening, according to some embodiments.

FIG. 22C is a diagram depicting a top view of an example semiconductor structure after a dielectric has been filled in an opening, according to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

As used herein, the terms such as “first,” “second” and “third” describe various elements, components, regions, layers and/or sections, these elements, components, regions, layers, and/or sections should not be limited by these terms. These terms may be only used to distinguish one element, component, region, layer, or section from another. The terms such as “first,” “second” and “third” when used herein do not imply a sequence or order unless clearly indicated by the context.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5° less than or equal to ±4°, less than or equal to ±3°, less than or equal to ±2°, less than or equal to ±1°, less than or equal to ±0.5°, less than or equal to ±0.1°, or less than or equal to ±0.05°.

Gate structures in field effect transistors may extend across two or more transistors. For example, the gate structures may be formed as long “lines” across the active regions of the substrate, such as the fin structures. Once the gate structures are formed, a patterning process “cuts” the long gate structure to shorter sections according to a desired layout. In other words, the patterning process removes portions of the long gate structure and portions of interlayer dielectric (ILD) structure surrounding the long gate structure to form one or more “cuts” and separate the long line into shorter sections. This process may be referred to as a cut-metal-gate (CMG) process. Subsequently, the cuts formed between the separated sections of the long gate structure are filled with a gap fill material, such as a dielectric material of silicon nitride (SiN). Silicon nitride not only electrically isolates adjacent sections of the long gate structure, but also protects the exposed gate structure layers from oxygen diffusion.

A similar process, referred to as cut-dummy-poly (CPO), involves removing portions of a long hybrid or dummy gate structure and portions of interlayer dielectric (ILD) structure surrounding the long hybrid or dummy gate structure to form one or more “cuts” and separate the long line of the hybrid gate structure into shorter sections. Subsequently, the cuts formed between the separated sections of the hybrid gate structure are filled with a gap fill structure, such as a dielectric material of SN. The CPO process may be performed before metal gate (MG) fill, whereas the CMG process may be performed after MG fill. Each process has its own advantages and disadvantages.

In novel technology devices, such as FinFET, NanosheetFET, GAAFET (gate all around FET), and others, isolating a metal gate (MG) through a cut process can become difficult due to a small MG critical dimension (CD) (e.g., shrinking pitch). Embodiments will now be described with respect to particular examples including GAAFET manufacturing processes. Embodiments, however, are not limited to the examples provided herein, and the ideas may be implemented in a wide array of embodiments. The subject matter disclosed herein may be applied to the CPO and the CMG processes.

While the figures illustrate various embodiments of a semiconductor device, additional features may be added in the semiconductor device depicted in the figures and some of the features described below can be replaced, modified, or eliminated in other embodiments of the semiconductor device.

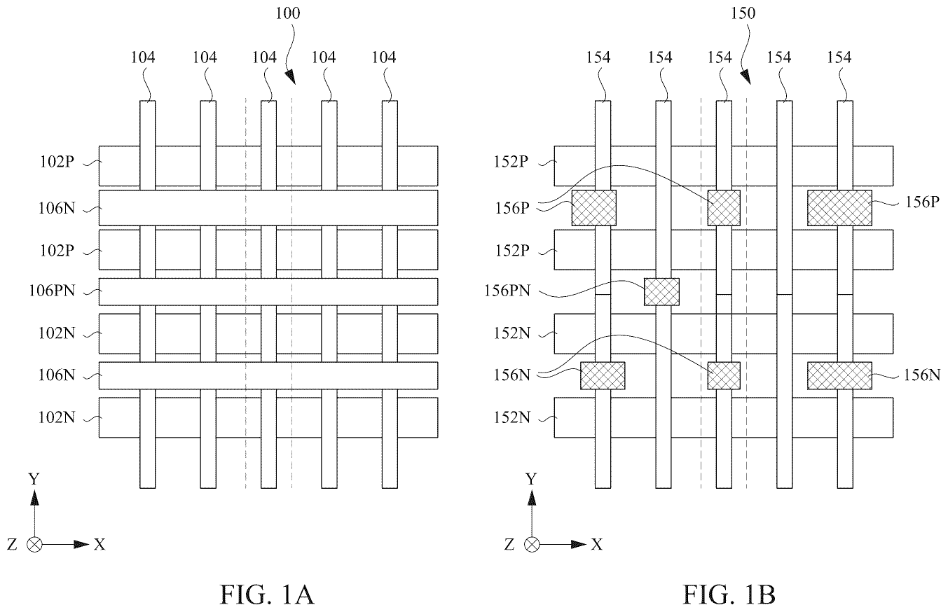

FIG. 1A is a partial top view of a semiconductor device 100 during a stage of fabrication that illustrates isolation cuts that are made to gate structures. The example semiconductor device 100 includes a plurality of fins 102P of a first polarity type (p-type in this example) and a plurality of fins 102N of a second polarity type (n-type in this example) extending laterally in an X-direction. The example semiconductor device 100 further includes a plurality of polysilicon gate structures 104 extending laterally in a Y-direction across the plurality of fins 102P of the first polarity type (e.g., p-type) and the plurality of fins 102N of the second polarity type (e.g., n-type). In this example, the fin to fin pitch is from about 50 to 100 nm and the cut process (CPO or CMG) is considered to provide an isolation cut. Shown are a plurality of isolation cuts 106P, 106N, 106PN wherein each isolation cut 106P, 106N, 106PN (e.g., cut LT) comprises a long trench that separates many polysilicon gate structures 104. The isolation cuts 106P are made to gate structures 104 between p-type transistors, the isolation cuts 106N are made to gate structures 104 between n-type transistors, and the isolation cuts 106PN are made to gate structures 104 between a p-type transistor and an n-type transistor.

FIG. 1B is a partial top view of a semiconductor device 150 during a stage of fabrication that illustrates dense cuts that are made to gate structures. The example semiconductor device 150 includes a plurality of fins 152P of a first polarity type (p-type in this example) and a plurality of fins 152N of a second polarity type (n-type in this example) extending laterally in an X-direction. The example semiconductor device 150 further includes a plurality of polysilicon gate structures 154 extending laterally in a Y-direction across the plurality of fins 152P of the first polarity type (e.g., p-type) and the plurality of fins 152N of the second polarity type (e.g., n-type). In this example, the fin to fin pitch is from about 50 to 100 nm and the cut process (CPO or CMG) is considered to provide a dense cut. Shown are a plurality of dense cuts 156P, 156N, 156PN wherein each dense cut 156P, 156N, 156PN comprises a short trench that separates a limited number of polysilicon gate structures 154. The dense cuts 156P are made to gate structures 154 between p-type transistors, the dense cuts 156N are made to gate structures 154 between n-type transistors, and the dense cuts 156PN are made to gate structures 154 between a p-type transistor and an n-type transistor.

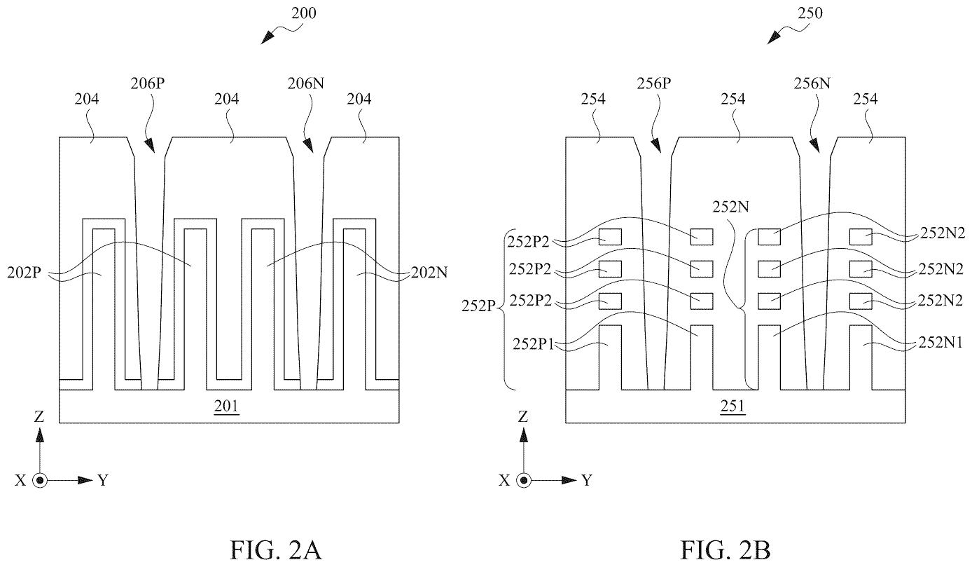

FIG. 2A is a cross-sectional view of a semiconductor device 200 (e.g., semiconductor device 100 or semiconductor device 150) during a stage of fabrication that illustrates cuts (isolation cuts or dense cuts) that are made to gate structures for a FinFET. The example semiconductor device 200 includes a plurality of fins 202P of a first polarity type (p-type in this example) for FinFET transistors extending vertically in a Z-direction from a substrate 201 and a plurality of fins 202N of a second polarity type (n-type in this example) for FinFET transistors extending vertically in a Z-direction from the substrate 201. The example semiconductor device 200 further include a polysilicon gate structure 204 extending laterally in a Y-direction across the plurality of fins 202P of the first polarity type (e.g., p-type) and the plurality of fins 202N of the second polarity type (e.g., n-type). The example semiconductor device 200 further includes a first cut 206P and a second cut 206N. The first cut 206P may be an isolation cut or a dense cut, and the second cut 206N may be an isolation cut or a dense cut. The first cut 206P is made to gate structure 204 between p-type transistors, and the second cut 206N is made to gate structure 204 between n-type transistors.

FIG. 2B is a cross-sectional view of a semiconductor device 250 (e.g., semiconductor device 100 or semiconductor device 150) during a stage of fabrication that illustrates cuts (isolation cuts or dense cuts) that are made to gate structures for GAAFETs. The example semiconductor device 250 includes a plurality of fins 252P of a first polarity type (p-type in this example) for GAAFETs extending vertically in a Z-direction from a substrate 251 and a plurality of fins 252N of a second polarity type (n-type in this example) for GAAFETs extending vertically in a Z-direction from the substrate 251. A fin 252P includes a mesa portion 252P1 extending vertically from the substrate 251 and one or more nanostructures 252P2 vertically stacked over the mesa portion 252P1. Similarly, a fin 252N includes a mesa portion 252N1 extending vertically from the substrate 251 and one or more nanostructures 252N2 vertically stacked over the mesa portion 252N1. The example semiconductor device 250 further include a polysilicon gate structure 254 extending laterally in a Y-direction across the plurality of fins 252P of the first polarity type (e.g., p-type) and the plurality of fins 252N of the second polarity type (e.g., n-type). The example semiconductor device 250 further includes a first cut 256P and a second cut 256N. The first cut 256P may be an isolation cut or a dense cut, and the second cut may be an isolation cut or a dense cut. The first cut 256P is made to gate structure 254 between p-type transistors, and the second cut 256N is made to gate structure 254 between n-type transistors.

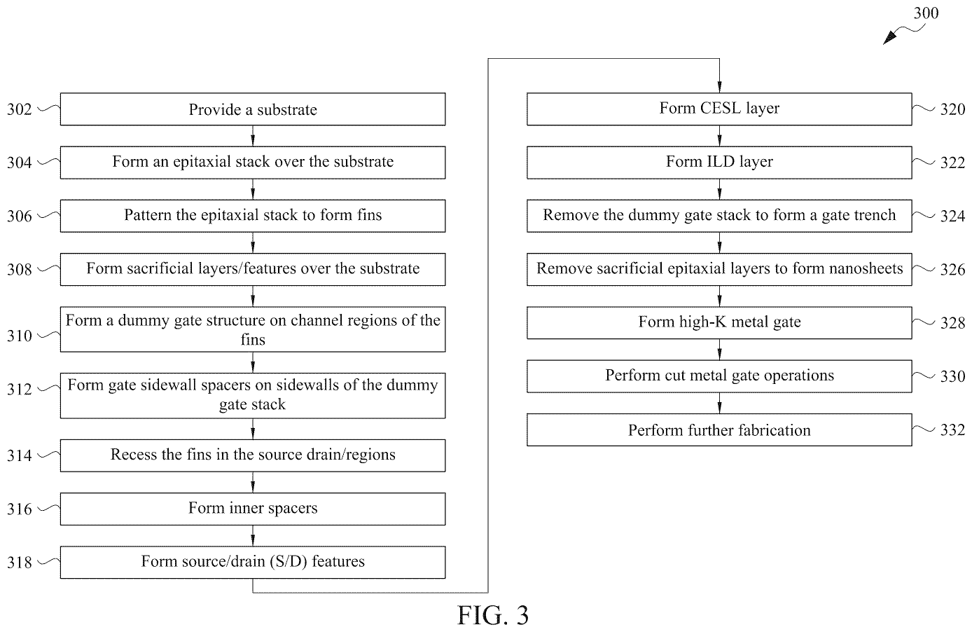

FIG. 3 is a flow chart depicting an example method 300 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAAFET device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

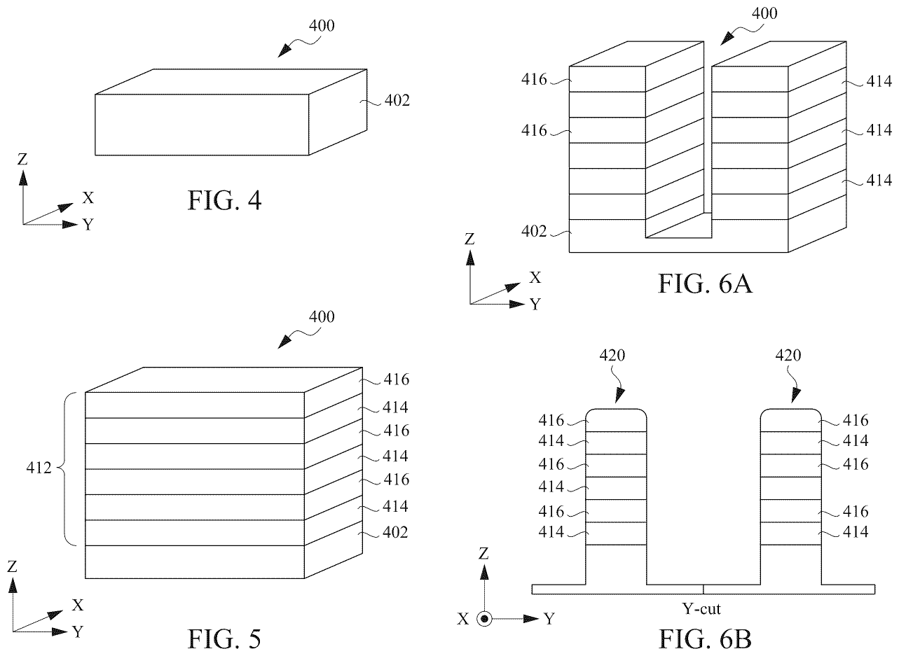

FIG. 3 is described in conjunction with FIGS. 4-5, 6A-6C, 7, 8A-8B, and 9-17, which illustrate a semiconductor device 400 or structure at various stages of fabrication in accordance with some embodiments. The method 300 is merely an example and is not intended to limit the present disclosure beyond what is explicitly recited in the claims. Additional steps may be provided before, during, and after method 300, and some of the steps described can be moved, replaced, or eliminated for additional embodiments of method 300. Additional features may be added in the semiconductor device 400 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 300, include any descriptions given with reference to the figures, as with the remainder of the method and exemplary figures provided in this disclosure, are merely exemplary and are not intended to be limiting beyond what is specifically recited in the claims that follow.

FIGS. 4-5, 6A-6C, 7, 8A-8B, and 9-17, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 302, the example method 300 includes providing a substrate. Referring to the example of FIG. 4, in an embodiment of block 302, a substrate 402 is provided for forming the semiconductor device 400. In some embodiments, the substrate 402 may be a semiconductor substrate such as a silicon (Si) substrate. In some embodiments, the substrate 402 includes a single crystalline semiconductor layer on at least its surface portion. The substrate 402 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 402 may include a compound semiconductor and/or an alloy semiconductor. The substrate 402 may include various layers, including conductive or insulating layers formed on a semiconductor substrate. The substrate 402 may include various doping configurations depending on design requirements. For example, different doping profiles (e.g., n wells, p wells) may be formed on the substrate 402 in regions designed for different device types (e.g., n-type field effect transistors (NFET), p-type field effect transistors (PFET). The suitable doping may include ion implantation of dopants and/or diffusion processes. The substrate 402 has isolation features (e.g., shallow trench isolation (STI) features) interposing the regions providing different device types. Further, the substrate 402 may be strained for performance enhancement, may include a silicon-on-insulator (SOI) structure, and/or have other suitable enhancement features.

At block 304, the example method 300 then includes forming an epitaxial stack over the substrate that includes a plurality of epitaxial layers. Referring to the example of FIG. 5, in an embodiment of block 304, an epitaxial stack 412 is formed over the substrate 402. The epitaxial stack 412 includes sacrificial epitaxial layers 414 of a first composition interposed by channel epitaxial layers 416 of a second composition. The first and second composition can be different. In an embodiment, the sacrificial epitaxial layers 414 are formed from SiGe and the channel epitaxial layers 416 are formed from silicon (Si). However, other embodiments are possible including those that provide for a first composition and a second composition having different oxidation rates and/or etch selectivity. In some embodiments, the sacrificial epitaxial layer 414 includes SiGe and the channel epitaxial layer 416 includes silicon (Si). However, other embodiments are possible including those that provide for a first composition and a second composition having different oxidation rates and/or etch selectivity. In some embodiments, the sacrificial epitaxial layer 414 includes SiGe and where the channel epitaxial layer 416 includes Si, the Si oxidation rate of the channel epitaxial layer 416 is less than the SiGe oxidation rate of the sacrificial epitaxial layer 414. It is noted that three (3) layers each of epitaxial layers 414 and 416 are illustrated in FIG. 3, which is for illustrative purposes only and not intended to be limiting beyond what is specifically recited in the claims. In various embodiments, any number of epitaxial layers can be formed in the epitaxial stack 412; the number of layers depending on the desired number of channel regions for the device 400. In some embodiments, the number of channel epitaxial layers 416 is between 2 and 10, such as 3, 4 or 5.

In some embodiments, the sacrificial epitaxial layer 414 has a thickness ranging from about 4 nm to about 12 nm. The sacrificial epitaxial layers 414 may be substantially uniform in thickness. In some embodiments, the channel epitaxial layer 416 has a thickness ranging from about 3 nm to about 6 nm. In some embodiments, the channel epitaxial layers 416 of the stack are substantially uniform in thickness.

As described in more detail below, the channel epitaxial layer 416 may serve as channel region(s) for a subsequently formed multi-gate device and its thickness is chosen based on device performance considerations. The sacrificial epitaxial layer 414 may serve to reserve a spacing (or referred to as a gap) between adjacent channel region(s) for a subsequently formed multi-gate device and its thickness is chosen based on device performance considerations.

By way of example, epitaxial growth of the epitaxial stack 412 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 416, include the same material as the substrate 402, such as silicon (Si). In some embodiments, the epitaxially grown layers 414 and 416 include a different material than the substrate 402. As stated above, in at least some examples, the sacrificial epitaxial layer 414 includes an epitaxially grown Si₁₋ₓGex layer (e.g., x is about 25^{˜}55%) and the channel epitaxial layer 416 includes an epitaxially grown Si layer. Alternatively, in some embodiments, either of the sacrificial epitaxial layers 414 and channel epitaxial layers 416 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 414 and channel epitaxial layers 416 may be chosen based on providing differing oxidation and etch selectivity properties. In various embodiments, the epitaxial layers 414 and 416 are substantially dopant-free (i.e., having an extrinsic dopant concentration from about 0 cm⁻³ to about 1×1017 cm⁻³), where for example, no intentional doping is performed during the epitaxial growth process.

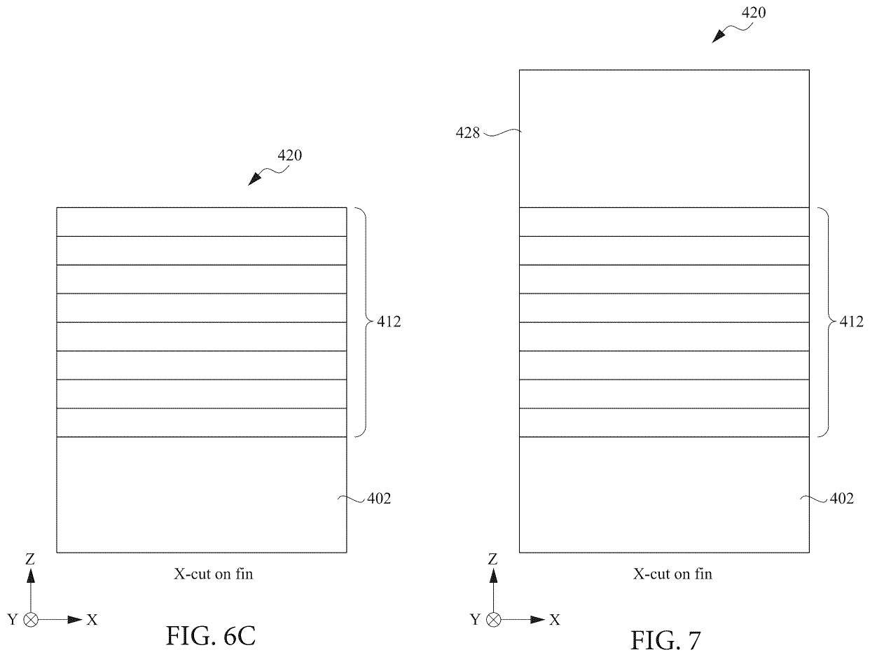

At block 306, the example method 300 includes patterning the epitaxial stack to form semiconductor fins (also referred to as fins). Referring to the example of FIGS. 6A, 6B, and 6C, in an embodiment of block 306, a plurality of fins 420 extending from the substrate 402 are formed. In various embodiments, each of the fins 420 includes an upper portion of the interleaved epitaxial layers 414 and 416 and a bottom portion (mesa portion) protruding from the substrate 402.

The fins 420 may be fabricated using suitable processes including photolithography and etch processes. The photolithography process may include forming a photoresist layer over the substrate 402 (e.g., over the epitaxial stack 412), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 402, and epitaxial stack 412 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 308, the example method 300 includes forming one or more sacrificial layers/features over the substrate. Referring to the example of FIG. 7, in an embodiment of block 308, a sacrificial gate dielectric layer (not shown) is blanket deposited over the fin 420, which is formed over the substrate 402. A sacrificial gate electrode layer 428 is then blanket deposited on the sacrificial gate dielectric layer and over the substrate 402. The sacrificial gate electrode layer 428 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 428 may be deposited using CVD, including LPCVD and PECVD, PVD, ALD, or other suitable processes.

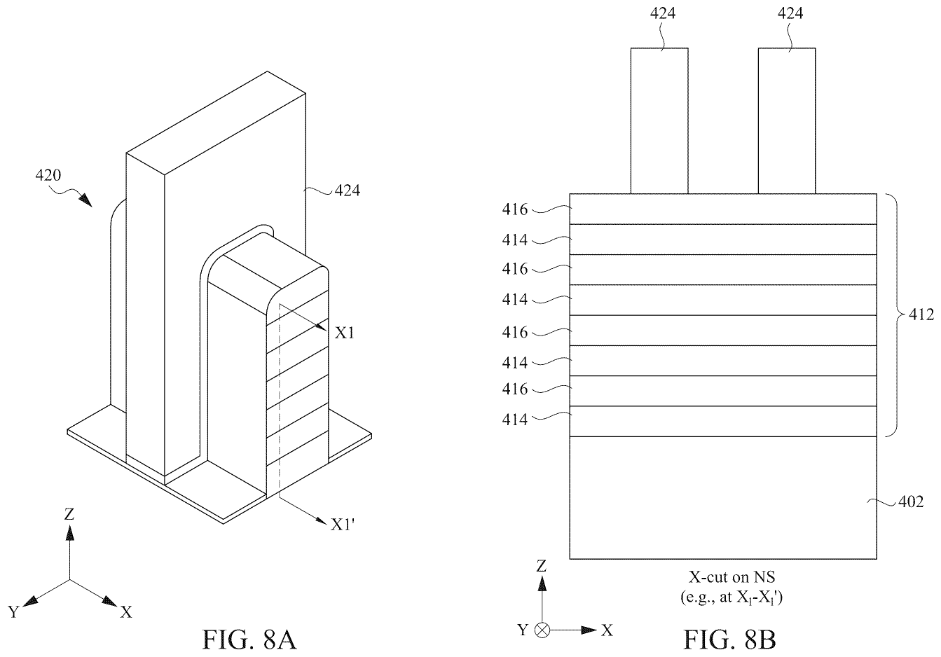

At block 310, the example method 300 includes patterning the one or more sacrificial layers/features to form a dummy gate structure on channel regions of the fins. Referring to the example of FIGS. 8A and 8B, in an embodiment of block 310, a sacrificial gate structure 424 is formed over portions of the fins 420 which are to be channel regions. The sacrificial gate structure 424 defines the channel regions of a GAAFET device. The sacrificial gate structure 424 includes a sacrificial gate dielectric layer and a sacrificial gate electrode layer 428. The sacrificial gate structure 424 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 424. By patterning the sacrificial gate structure 424, the fins 420 are partially exposed on opposite sides of the sacrificial gate structure 424, thereby defining source/drain (S/D) regions. In this disclosure, a source and a drain are interchangeably used, and the structures thereof are substantially the same.

The sacrificial gate structure 424 is subsequently removed as discussed with reference to block 324 of the method 300 and will be replaced by a final gate stack at a subsequent processing stage of the device 400. In particular, the sacrificial gate structure 424 is replaced at a later processing stage by a high-K dielectric layer (HK) and metal gate electrode (MG) as discussed below.

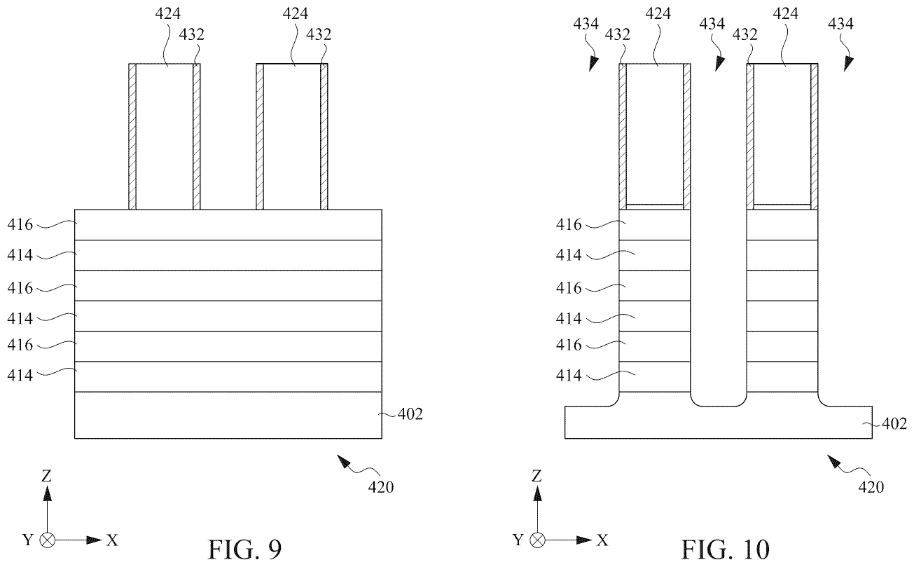

At block 312, the example method 300 includes forming gate sidewall spacers on sidewalls of the sacrificial gate structure. Referring to the example of FIG. 9, in an embodiment of block 312, gate sidewall spacers 432 are formed on sidewalls of the sacrificial gate structure 424. In various embodiments, the gate sidewall spacers 432 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 432 include multiple layers, such as main spacer walls, liner layers, and the like. By way of example, the gate sidewall spacers 432 may be formed by depositing a dielectric material layer over the sacrificial gate structure 424 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 420 adjacent to and not covered by the sacrificial gate structure 424 (e.g., S/D regions). The dielectric material layer may remain on the sidewalls of the sacrificial gate structure 424 as gate sidewall spacers 432. In some embodiments, the etching-back process may include a wet etch process, a dry etch process, a multiple-step etch process, and/or a combination thereof. The gate sidewall spacers 432 may have a thickness ranging from about 5 nm to about 20 nm.

At block 314, the example method includes recessing the fins in the source drain/regions. Referring to the example of FIG. 10, in an embodiment of block 314, the fin 420 is recessed in the source drain/regions. The stacked epitaxial layers 414 and 416 are etched down at the S/D regions to form a recess 434. In various embodiments, the recessing is performed by a suitable etching process, such as a dry etching process, a wet etching process, or an RIE process. Dry etching may be implemented using an etchant including a bromine-containing gas (e.g., HBr and/or CHBR₃), a fluorine-containing gas (e.g., CF₄, SF₆, CH₂F₂, CHF₃, and/or C₂F₆), other suitable gases, or combinations thereof.

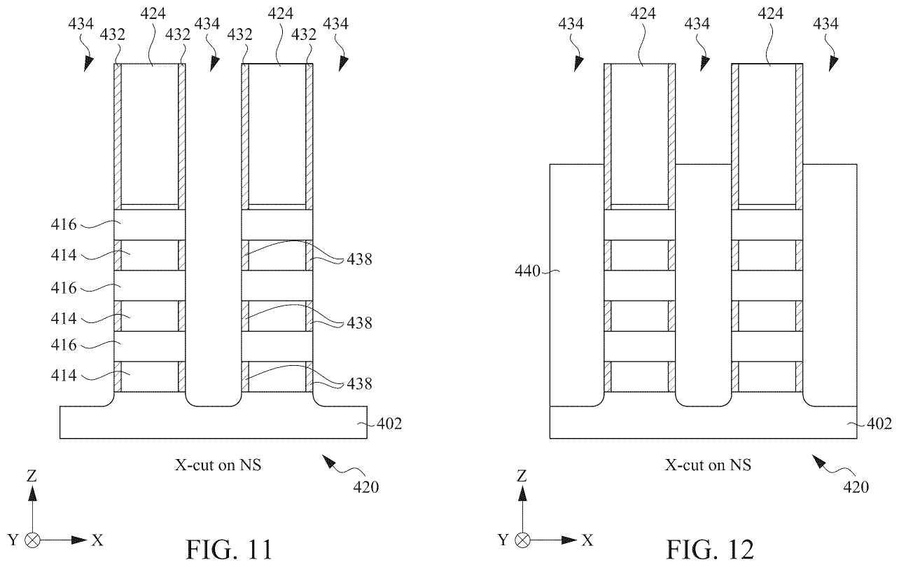

At block 316, the example method 300 Includes forming inner spacers. Forming inner spacers may include recessing sacrificial epitaxial layers (e.g., SiGe), depositing inner spacer material, and etching back inner spacer material. Referring to the example of FIG. 11, in an embodiment of block 316, inner spacers 438 are formed. The sacrificial epitaxial layers 414 have been etched back. The sacrificial epitaxial layers 414 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 316 lateral ends of the sacrificial epitaxial layers 414 that are exposed in the recess 434 may be selectively oxidized to increase the etch selectivity between the epitaxial layers 414 and 416. In some examples, the oxidation process may be performed by exposing the device 400 to a wet oxidation process, a dry oxidation process, or a combination thereof.

The inner spacers 438 may include silicon oxides, silicon nitrides, silicon carbides, silicon carbide nitride, silicon oxide carbide, silicon carbide oxynitride, and/or other suitable dielectric materials. In some embodiments, the inner spacer material layer is deposited as a conformal layer. The inner spacer material layer can be formed by ALD or any other suitable method. After the inner spacer material layer is formed, an etching operation may be performed to partially remove the inner spacer material layer. In various embodiments, the inner spacers 438 are formed form the same material as the gate sidewall spacers 432. In various embodiments, the gate sidewall spacers 432 and the inner spacers 438 are formed from SiOCN.

At block 318, the example method 300 includes forming source/drain (S/D) features. Referring to the example of FIG. 12, in an embodiment of block 318, epitaxial S/D features 440 are formed in recess 434. In some embodiments, the epitaxial S/D features 440 include silicon for NFETs and SiGe for PFETs. In some embodiments, the epitaxial S/D features 440 are formed by an epitaxial growth method using CVD, ALD, or molecular beam epitaxy (MBE). The epitaxial S/D features 440 are formed in contact with the channel epitaxial layers 416 and separated from the sacrificial epitaxial layers 414 by the inner spacers 438.

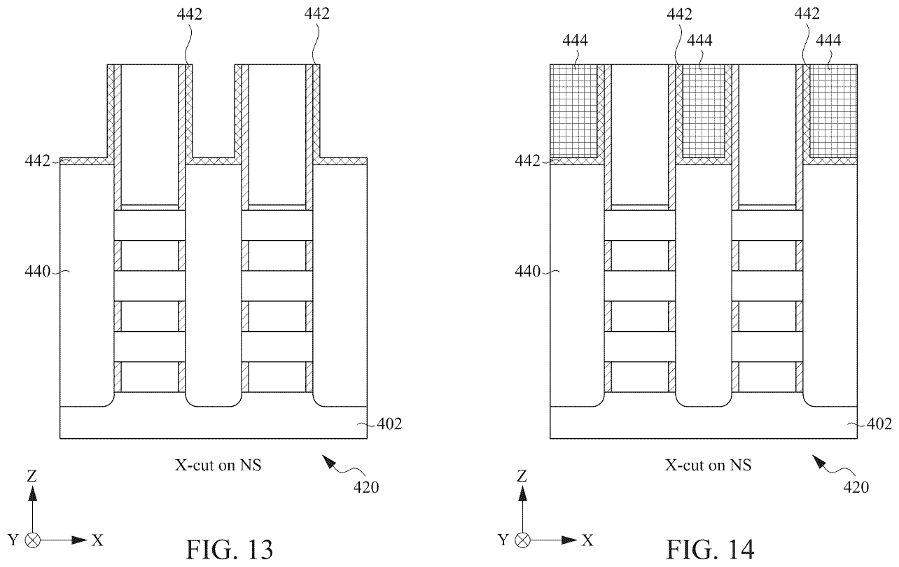

At block 320, the example method 300 includes forming a CESL layer. Referring to the example of FIG. 13, in an embodiment of block 320, a CESL layer 442 is formed over the S/D features 440. The CESL layer 442 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 442 is formed from SiN.

At block 322, the example method 300 includes forming an ILD layer. Referring to the example of FIG. 14, in an embodiment of block 322, an interlayer dielectric (ILD) layer 444 is formed over the CESL layer 442. The ILD layer 444 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 444 may be formed by PECVD, flowable CVD (FCVD), or other suitable methods. In some embodiments, forming the ILD layer 444 further includes performing a CMP process to planarize a top surface of the device 400, such that the top surfaces of the sacrificial gate structure 424 are exposed.

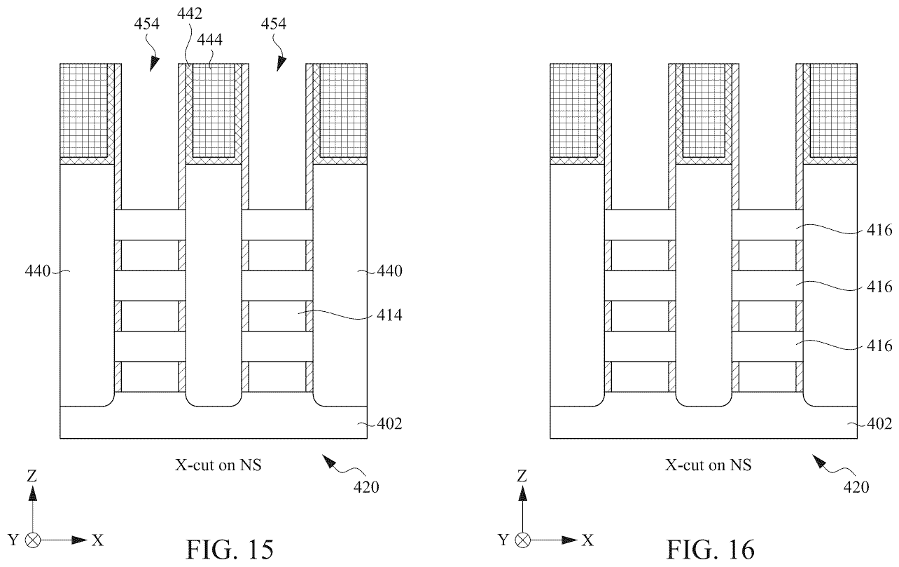

At block 324, the example method 300 includes removing the dummy gate stack to form a gate trench. Referring to the example of FIG. 15, in an embodiment of block 324, the sacrificial gate structure 424 has been removed to form a gate trench 454. The gate trench 454 exposes the fin 420 in the channel region(s). The ILD layer 444 and the CESL layer 442 protects the epitaxial S/D features 440 during the removal of the sacrificial gate structure 424. The sacrificial gate structure 424 can be removed using plasma dry etching and/or wet etching. When the sacrificial gate electrode layer is polysilicon and the ILD layer 444 is an oxide, a wet etchant such as a TMAH solution can be used to selectively remove the sacrificial gate electrode layer. The sacrificial gate dielectric layer is thereafter removed using plasma dry etching and/or wet etching.

At block 326, the example method 300 includes removing the sacrificial epitaxial layers to form nanosheets. Referring to the example of FIG. 16, in an embodiment of block 326, sacrificial epitaxial layers 414 have been removed thereby releasing channel members from the channel region of the GAAFET device. In the illustrated embodiment, channel members are channel epitaxial layers 416 in the form of nanosheets. In various embodiments, the channel epitaxial layers 416 include silicon, and the sacrificial epitaxial layers 414 include silicon germanium. In various embodiments, the plurality of sacrificial epitaxial layers 414 were selectively removed via a selective removal process that included oxidizing the plurality of sacrificial epitaxial layers 414 using a suitable oxidizer, such as ozone. Thereafter, the oxidized sacrificial epitaxial layers 414 were selectively removed via a dry etching process, for example, by applying an HCl gas at a temperature of about 500 degrees Celsius to about 700 degrees Celsius, or applying a gas mixture of CF₄, SF₆, and CHF₃.

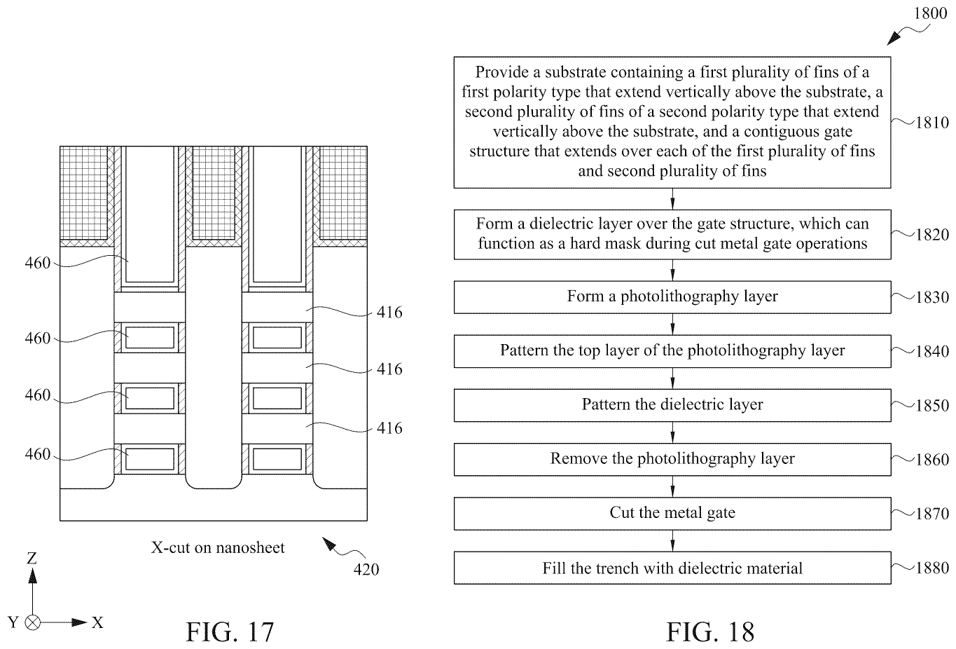

At block 328, the example method 300 includes forming high-K metal gate structures. Referring to the example of FIG. 17, in an embodiment of block 328, a fin 420 includes a mesa portion 458 and a plurality of nanosheets 416 vertically stacked over the mesa portion. A gate structure 460 is formed and wrapped around the nanosheets 416. In various embodiments, the gate structure is the gate of a multi-gate transistor. In various embodiments, the gate structure is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 416, and the interfacial layer is interposed between the high-k dielectric layer and the nanosheets 416. The interfacial layer may include a dielectric material such as silicon oxide (SiO2) or silicon oxynitride (SiON), and may be formed by chemical oxidation, thermal oxidation, atomic layer deposition (ALD), CVD, and/or other suitable methods. The high-k dielectric layer may include hafnium oxide (HfO2), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO2—Al2O3) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

At block 330, the example method 300 includes performing cut metal gate operations to isolate gate structures for various transistors. In various embodiments, the cut metal gate operations may result in one or more dense cuts and/or isolation cuts.

At block 332, the example method 300 includes performing further fabrication. A semiconductor device may undergo further processing to form various features and regions known in the art. For example, subsequent processing may form contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 300, and some process steps described above may be replaced or eliminated in accordance with various embodiments of the method 300.

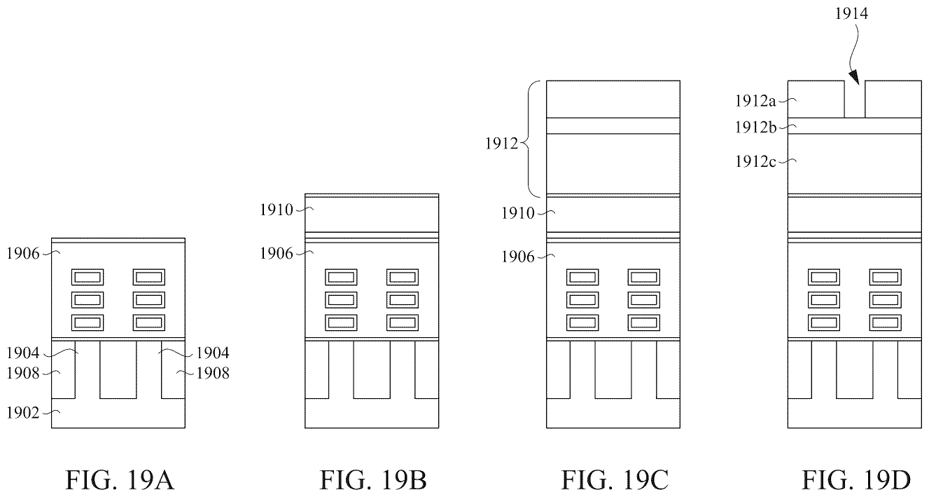

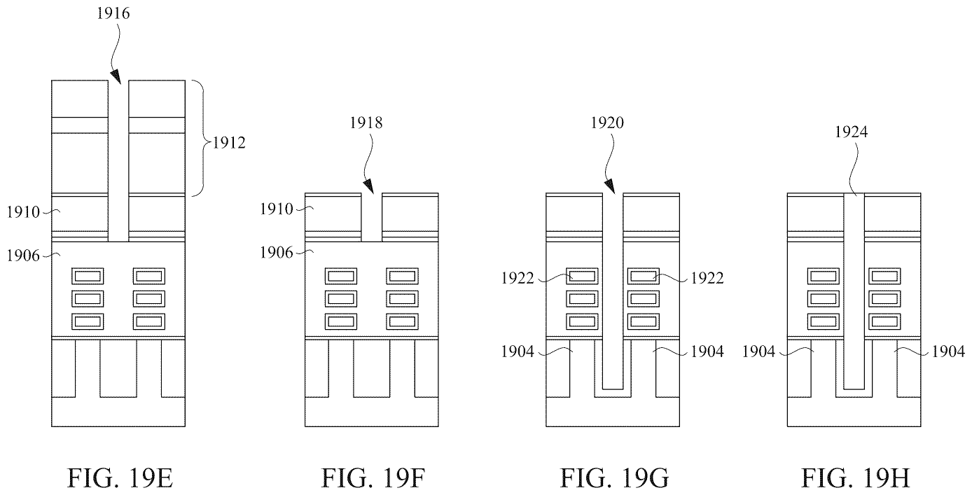

FIG. 18 is a flow chart of an example cut metal gate process 1800, in accordance with some embodiments. Additional fabrication operations may be performed between the various operations of process 1800 and may be omitted merely for clarity and ease of description. These various operations are within the spirit and the scope of this disclosure. Moreover, not all operations may be required to perform the disclosure provided herein. Additionally, some of the operations may be performed simultaneously, or in a different order than the ones shown in FIG. 18. Accordingly, it is understood that additional processes can be provided before, during, and/or after process 1800, and that some other processes may only be briefly described herein. For illustrative purposes, process 1800 will be described with reference to the embodiments shown in FIGS. 19A-19H , wherein FIGS. 19A-19H illustrates example stages of an example cut (e.g., dense cut or isolation cut) during performance of the various blocks of process 1800. The figures provided to describe process 1800 are for illustrative purposes only and are not to scale. In addition, the figures may not reflect the actual geometry of the actual structures, features, or films. Some structures, films, or geometries may have been deliberately augmented for illustrative purposes.

The example process 1800 starts at block 1810, with a substrate containing a plurality of fins that extend vertically above the substrate and a contiguous gate structure that extends over the plurality of fins. Referring the example of FIG. 19A, in an embodiment of block 1810, a substrate 1902 contains a plurality of fins 1904 that extend vertically above the substrate and a contiguous gate structure 1906 that extends over the plurality of fins. Shallow trench isolation (STI) material 1908 is disposed between the plurality of fins.

At block 1820, the example process 1800 includes forming a dielectric layer over the gate structure, which can function as a hard mask during cut metal gate operations. The dielectric layer may be formed by deposition operations. Referring to the example of FIG. 19B, in an embodiment of block 1820, a dielectric layer 1910 is formed over the contiguous gate structure 1906.

At block 1830, the example process 1800 includes forming a photolithography layer over the dielectric layer. The photolithography layer may be formed by deposition operations. Referring to the example of FIG. 19C, in an embodiment of block 1830, a photolithography layer 1912 comprising a top layer 1912a, a middle layer 1912b, and a lower layer 1912c are formed over the dielectric layer 1910.

At block 1840, the example process 1800 includes patterning the top layer of the photolithography layer. Referring to the example of FIG. 19D, in an embodiment of block 1840, the top layer 1912a of the photolithography layer 1912 is patterned to form an opening 1914 between two fins 1904.

At block 1850, the example process 1800 includes patterning the dielectric layer. In various embodiments, the dielectric layer is patterned by etching the middle and lower layers of the photolithography to extend the opening in the top layer toward the dielectric layer and patterning the dielectric layer by further extending the opening through the dielectric layer. In various embodiments, the dielectric layer formed above and around the contiguous gate structure is patterned to form a first recess between the pair of fins. Referring to the example of FIG. 19E, in an embodiment of block 1850, a first recess 1916 is formed in the dielectric layer 1910 and the photolithography layer 1912 between the pair of fins 1904.

At block 1860, the example process 1800 includes removing the photolithography layer. Referring to the example of FIG. 19F, in an embodiment of block 1860, the photolithography layer 1912 illustrated in FIG. 19E has been removed leaving the dielectric layer 1910 with a second opening 1918 in the dielectric layer 1910 above the contiguous gate structure 1906. Various etching techniques may be employed to remove the photolithography layer 1912.

At block 1870, the example process 1800 includes cutting the contiguous metal gate structure. In various embodiments, the contiguous metal gate structure is cut via an etching process (e.g., in a plasma dry etch chamber). In various embodiments, cutting the contiguous metal gate structure comprises performing an isolation cut that extends across a plurality of contiguous gate structures. In various embodiments, cutting the metal gate comprises performing a dense cut that extends across a first contiguous gate structure but does not extend across an adjacent contiguous gate structure that is parallel to the first contiguous gate structure.

A metal gate cut (CMG) is made in a manner that can prevent N-type work function metal (WFM) damage and P-type WFM metal damage. The CMG is made while controlling CMG profile roughness. In other words, a contiguous gate structure is separated between two fins thereby forming a metal gate cut without N-type WFM damage and P-type WFM metal damage in the gate structures that remain over the two fins. The metal gate cut has a tapered profile with a width that is wider at the top of the metal gate cut and narrower at the bottom of the metal gate cut. Surface roughness of the CMG profile is reduced by performing multiple series of smaller incremental cuts to achieve a desired cut length. The multiple series of smaller incremental cuts allow for improved CMG critical dimension (CD) control by reducing potential CMG overcut that can occur when larger incremental cuts are made. The improved CMG critical dimension (CD) control and the reduced CMG overcut can prevent WFM near nanosheets 1922 from being damaged during cutting the contiguous metal gate structure.

Cutting the contiguous metal gate structure results in forming a trench or opening that separates the continuous gate structure into two gate structure segments. In various embodiments, the trench or opening formed between the two gate structure segments extends into the STI material disposed between the pair of fins 1904.

Referring to the example of FIG. 19G, in an embodiment of block 1870, a trench 1920 is formed between the pair of fins 1904. In this example, the trench 1920 extends into the STI material 1908. Although not explicitly illustrated, WFM near nanostructures 1922 have not been damaged during the continuous metal gate cutting operations.

At block 1880, the example process 1800 includes filling the trench with dielectric material to form a gate isolation region (i.e., a metal gate cut) within the contiguous gate structure 1906. In various embodiments, the trench is filled with dielectric material by depositing dielectric material in the trench. The dielectric material in the trench isolates a first fin of the pair of fins from the other fin of the pair of fins. Referring to the example of FIG. 19H, in an embodiment of block 1880, a dielectric material layer 1924 is formed in the trench between a first fin 1904 and a second fin 1904. The dielectric material layer 1924 may include silicon nitride, silicon oxide, silicon oxynitride, silicon carbide, other insulating materials, and the like. In some embodiments, the dielectric material may include multiple materials or multiple layers. In some embodiments, the dielectric material may be formed by PVD, PECVD, CVD, ALD, or another suitable deposition method.

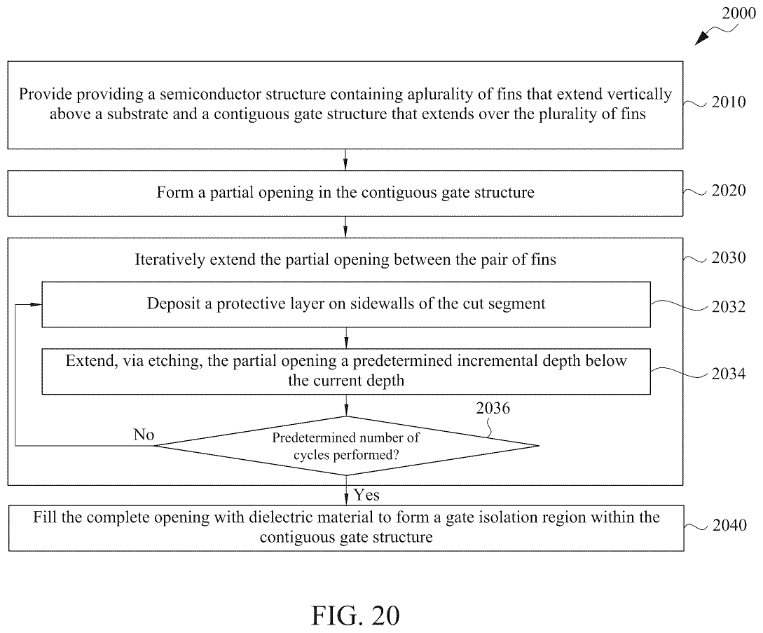

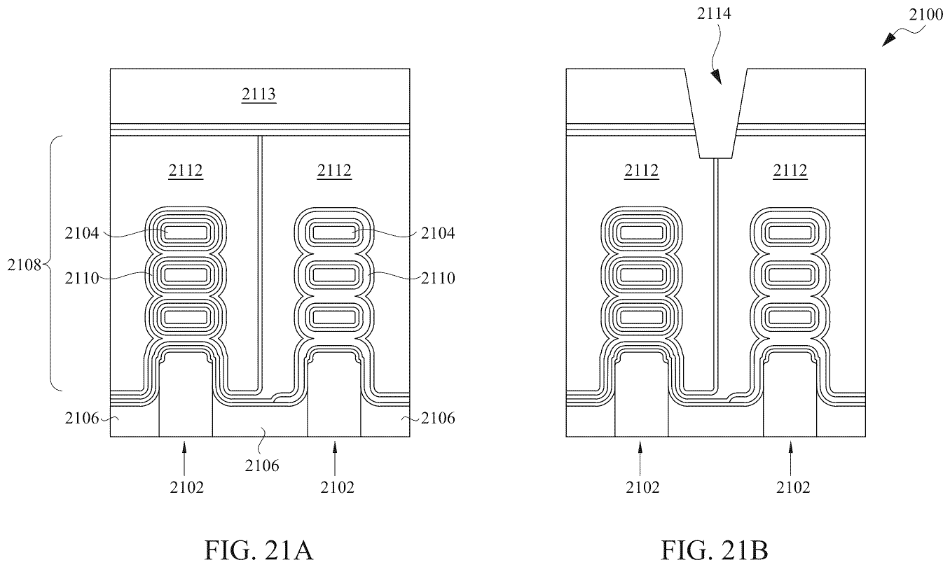

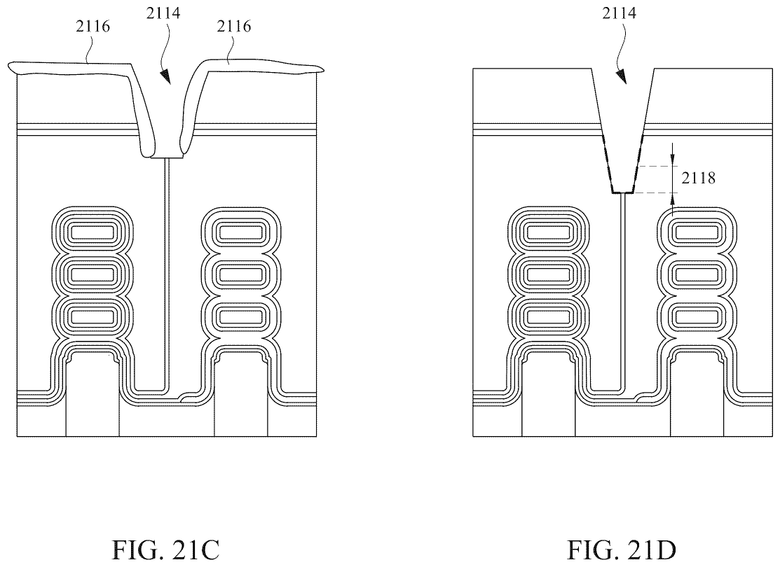

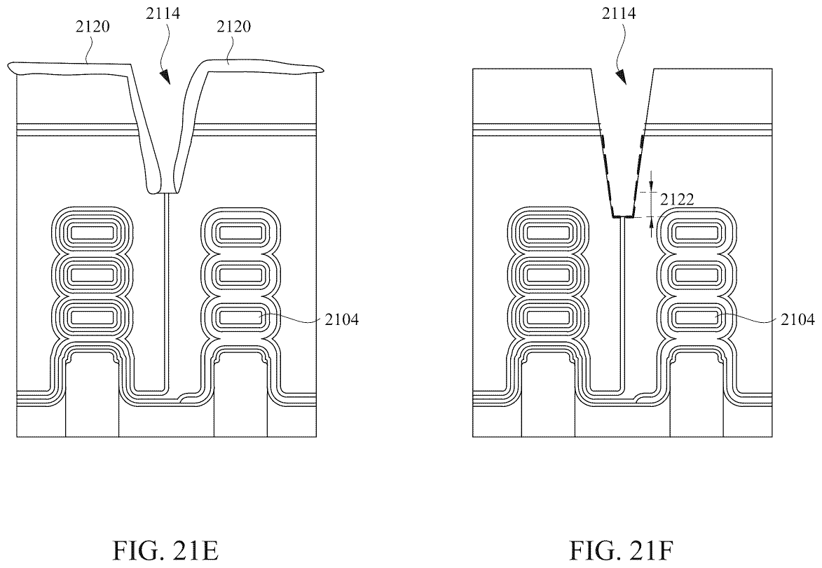

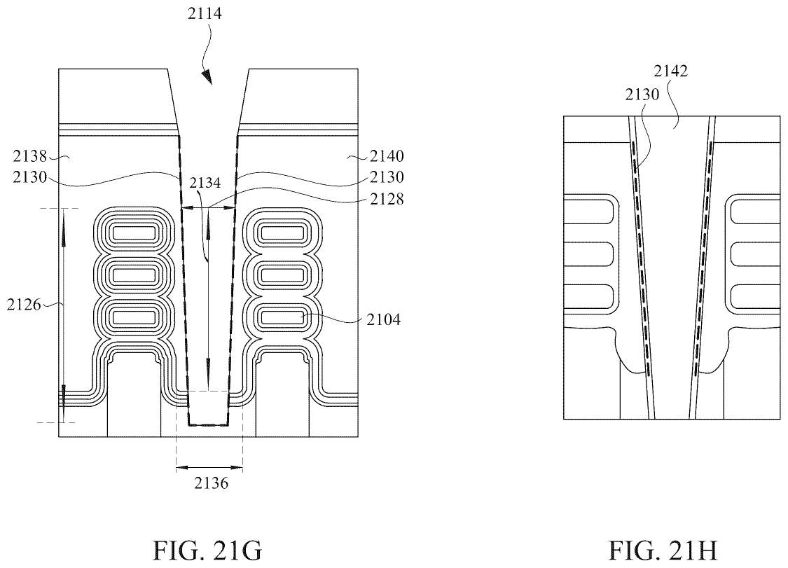

FIG. 20 is a flow diagram depicting an example method 2000 of cutting a contiguous metal gate structure, according to some embodiments. Additional fabrication operations may be performed between the various operations of method 2000 and may be omitted merely for clarity and ease of description. These various operations are within the spirit and the scope of this disclosure. Moreover, not all operations may be required to perform the disclosure provided herein. Additionally, some of the operations may be performed simultaneously, or in a different order than the ones shown in FIG. 20. Accordingly, it is understood that additional processes can be provided before, during, and/or after method 2000, and that some other processes may only be briefly described herein. For illustrative purposes, the blocks illustrated in FIG. 20 will be described with reference to FIGS. 21A through 21I, which show cross-sectional views of a semiconductor device at various stages of fabrication, according to some embodiments.

At block 2010, the method 2000 includes providing a semiconductor structure containing a plurality of fins that extend vertically above a substrate and a contiguous gate structure that extends over the plurality of fins. Referring to the example of FIG. 21A, in an embodiment of block 2010, a semiconductor structure 2100 containing a plurality of fins 2102 that extend vertically above a substrate (not shown), a plurality of nanosheets 2104 above the fins, shallow trench isolation (STI features 2106) around the fins and above the substrate, and a contiguous gate structure 2108 that extends over the plurality of fins and STI features 2106. The contiguous gate structure 2108 includes work function metal features (WFM 2110) around the nanosheets 2104 and gate fill material 2112 around the WFM 2110. The semiconductor structure 2100 also includes a mask layer 2113 above the gate fill material 2112.

At block 2020, the method 2000 includes forming a partial opening in the contiguous gate structure. Forming a partial opening in the contiguous gate structure I may include patterning a mask layer above the contiguous gate structure, for example, using the operations specified in block 1820 through block 1860 of FIG. 18, and transferring the pattern to the contiguous gate structure to form the partial opening in the contiguous gate structure between a pair of fins. An etching process may be performed to form the partial opening in the contiguous gate structure. Referring to the example of FIG. 21B, in an embodiment of block 2020, a partial opening 2114 is etched in the gate fill material 2112 and the mask layer 2113 between the pair of fins 2102.

At block 2030, the method 2000 includes iteratively extending the partial opening between the pair of fins. Block 2030 includes block 2032, block 2034, and block 2036.

At block 2032, the method 2000 includes depositing a protective layer on sidewalls of the cut segment. In various embodiments, the protective layer is deposited in a plasma processing chamber using one or more of SiCl₄, HBr, O₂, CH₄, and N₂ as a process gas. In various embodiments, the protective layer comprises a silicon oxide (SiO₂) or a carbon nitride (CN). In various embodiments, the protective layer has a thickness of about 5 Å to about 50 Å. A protective layer in this thickness range may allow the surface roughness of the subsequent CMG profile to be reduced and prevent WFM from being damaged. Referring to the example of FIG. 21C, in an embodiment of block 2032, a protective layer 2116 is deposited on sidewalls of the partial opening 2114 and above the mask layer 2113.

At block 2034, the method 2000 includes extending, via etching, the partial opening a predetermined incremental depth below the current depth. In various embodiments, the predetermined incremental depth is between about 5 nanometers (nm) and about 25 nm. This incremental depth range may allow the surface roughness of the subsequent CMG profile to be reduced, allow for improved CMG critical dimension (CD) control by reducing potential CMG overcut that can occur when larger incremental cuts are made, and prevent WFM from being damaged. Etching the opening to the predetermined incremental depth may include a plasma etching process. The plasma etching process may be, for example, an Atomic Layer Etching (ALE) process, an RIE process, or another process. In some embodiments, the plasma etching process is performed in a processing chamber with process gases being supplied into the processing chamber. Process gases may include one or more of CF₄, CH₃F, CHF₃, CH₄, Cl₂, C₄F₆, BCl₃, SiCl₄, HBr, O₂, or N₂. The predetermined incremental depth may be set based on the length of the plasma etching process in the processing chamber. In some embodiments, the plasma etching process may be performed for 8 seconds to achieve the predetermined incremental depth. Referring to the example of FIG. 21D, in an embodiment of block 2034, the partial opening 2114 has been extended a predetermined incremental depth 2118.

The process gases may be flowed into the processing chamber at a rate between about 5 sccm (standard cubic centimeters per minute) and about 1000 sccm. Carrier gases, such as nitrogen, argon, helium, xenon, or the like, may be used to carry process gases into the processing chamber. The plasma etching process may be performed using a bias voltage between about 0 volts and about 1000 volts, and having a power between about 50 watts and about 3000 watts. The plasma etching process may be performed at a temperature between about 50° C. and about 200° C. A pressure in the processing chamber may be between about 3 mTorr and about 5 Torr.

In some embodiments, the plasma is a direct plasma. In other embodiments, the plasma is a remote plasma that is generated in a separate plasma generation chamber connected to the processing chamber. Process gases may be activated into plasma by any suitable method of generating the plasma, such as using a transformer coupled plasma generator, inductively coupled plasma systems, magnetically enhanced reactive ion techniques, electron cyclotron resonance techniques, or the like.

At block 2036, the method 2000 includes determining if a predetermined number of cycles has been performed. In various embodiments, the predetermined number of cycles is at least 10 cycles. The predetermined number of cycles are performed to achieve a desired gate cut length while preventing N-type work function metal (WFM) damage and P-type WFM metal damage.

If the predetermined number of cycles has not been performed, the method includes returning to block 2032 to repeat a subsequent iteration of the etching cycle (block 2032 and block 2034). Referring to the example of FIG. 21E, in an embodiment of a second iteration of block 2032, a protective layer 2120 is deposited on sidewalls of the partial opening 2114 and above the mask layer 2113. Referring to the example of FIG. 21F, in an embodiment of a second iteration of block 2034, the partial opening 2114 has been extended a second predetermined incremental depth 2122.

If the predetermined number of cycles has been performed, the method includes moving to block 2040. Referring to the example of FIG. 21G, in an embodiment after the predetermined number of cycles have been performed, the partial opening 2114 have been extended to provide a complete opening 2124 at a desired cut length 2126 and a desired middle critical dimension (MCD 2128). The desired cut length 2126 is measured in the opening 2124 from the top of the contiguous gate structure 2108 to the bottom of the complete opening 2124, and the MCD 2128 is measured across the opening 2124 at the height of the WFM at the topmost nanosheet 2104.

The contiguous gate structure 2108 is separated into a first gate segment 2138 and a second gate segment 2140 between two fins 2102 thereby forming a metal gate cut 2130 without N-type WFM damage and P-type WFM metal damage in the gate structures that remain over the two fins 2102. The fins may be spaced a distance 2136 that is between about 15 nm and about 100 nm. A sidewall of the metal gate cut 2130 may be located from one or more adjacent fins 2102 a distance that is between about 4 nm and about 40 nm. By alternately etching to deepen the partial opening 2114 and then depositing a protective film over sidewalls of the partial opening 2114, the profile of the complete opening 2124 may have straighter sidewalls.

The complete opening 2124 is made while controlling metal gate cut profile roughness. Surface roughness of the metal gate cut 2130 is reduced by performing multiple series of smaller incremental cuts to achieve a desired cut length 2126. The multiple series of smaller incremental cuts allow for improved critical dimension (CD) control by reducing a potential overcut that can occur when larger incremental cuts are made. The improved CD control and the reduced overcut can prevent WFM near nanosheets 2104 from being damaged during cutting operations on the contiguous gate structure 2108. Referring to the example of FIG. 21H, in an embodiment after the predetermined number of cycles have been performed, the metal gate cut 2130 has a metal gate cut profile that is relatively smooth, wherein deviations from a completely smooth metal gate cut profile is minimized.

The metal gate cut 2130 has a tapered profile with a width that is wider at the top of the metal gate cut 2130 and narrower at the bottom of the metal gate cut 2130. Forming the opening may comprise generating a metal gate cut 2130 with a sidewall of the opening having a maximum delta distance (Δₘₐₓ) of about 10 Å or less from a slope line along the sidewall of the metal gate cut 2130. FIG. 21I is a diagram depicting an example sidewall of a metal gate cut 2130 with a slope line 2132 that extends from one end of the sidewall to another end of the sidewall. The sidewall at various points may deviate a delta distance from the slope line 2132. A maximum delta distance (Δₘₐₓ) of deviation may be no more than about 10 Å of deviation from the slope line 2132. In various embodiments, forming the opening may further comprise generating the metal gate cut 2130 with a ratio of the maximum delta distance (Δₘₐₓ) to the length of the metal gate cut sidewall (gate cut length 2134) of about 1 to about 100 or more. This ratio may allow the surface roughness of the subsequent CMG profile to be reduced, allow for improved CMG critical dimension (CD) control by reducing potential CMG overcut that can occur, and prevent WFM from being damaged. In various embodiments, forming the opening further comprises generating the metal gate cut 2130 with a sidewall of the opening having an average delta distance (Δ_{avg}) of about 5 Å or less from the slope line 2132 along the sidewall. In various embodiments, forming the opening further comprises generating the metal gate cut 2130 with a ratio of the average delta distance (Δ_{avg}) to the gate cut length 2134 of about 1 to about 200 or more.

The desired cut length 2126 of the complete opening 2124 as measured from the top of the contiguous gate structure 2108 to the bottom of the complete opening 2124 may be between about 20 nm and about 250 nm. The gate cut length 2134 may be between about 10 nm and about 100 nm. In some embodiments, the complete opening 2124 has a length: width aspect ratio between about 1 and about 20.

The etching process extends the partial opening 2114 completely through the contiguous gate structure 2108 to form complete opening 2124. The complete opening 2124 may extend into the STI features 2106 underneath the contiguous gate structure 2108. In some embodiments, the complete opening 2124 may extend through the STI features 2106 and into the substrate underneath the STI features 2106.

In some embodiments, after iteratively extending the partial opening 2114 between the pair of fins 2102, remaining residue from a protective film or other byproducts from the etching process may be removed using a cleaning process, which may include a wet cleaning process, a plasma process, or a combination. In some embodiments, the plasma process may include an oxygen plasma (e.g., an ashing process) or exposure to another type of plasma. In an embodiment, the wet cleaning process may include a wet etch, such as an anisotropic wet etch. The wet cleaning process may include the use of etchants such as HF, NH₄OH, HCl, H₂O₂, H₂SO₄, combinations thereof, or the like. The wet cleaning process may be performed at a temperature between about 0° C. and about 100° C., such as about 70° C. In some embodiments, the cleaning process includes evacuating residue material from the processing chamber using, e.g., a pump connected to the processing chamber. In some embodiments, a thorough cleaning process may reduce the chance of remaining conductive residue (e.g. from etched portions of the contiguous gate structure 2108) making undesirable electrical connections between regions of the contiguous gate structure 2108 across the complete opening 2124.

After cutting the contiguous gate structure 2108, the method 2000 at block 2040 may include filling the complete opening 2124 with dielectric material 2142 to form a gate isolation region within the contiguous gate structure 2108. In various embodiments, the complete opening 2124 is filled with dielectric material 2142 through deposition operations. The dielectric material 2142 in the trench isolates a first fin of the pair of fins 2102 from the other fin of the pair of fins 2102. The dielectric material 2142 may include silicon nitride, silicon oxide, silicon oxynitride, silicon carbide, other insulating materials, and the like. In some embodiments, the dielectric material may include multiple materials or multiple layers. In some embodiments, the dielectric material may be formed by PVD, PECVD, CVD, ALD, or another suitable deposition method.

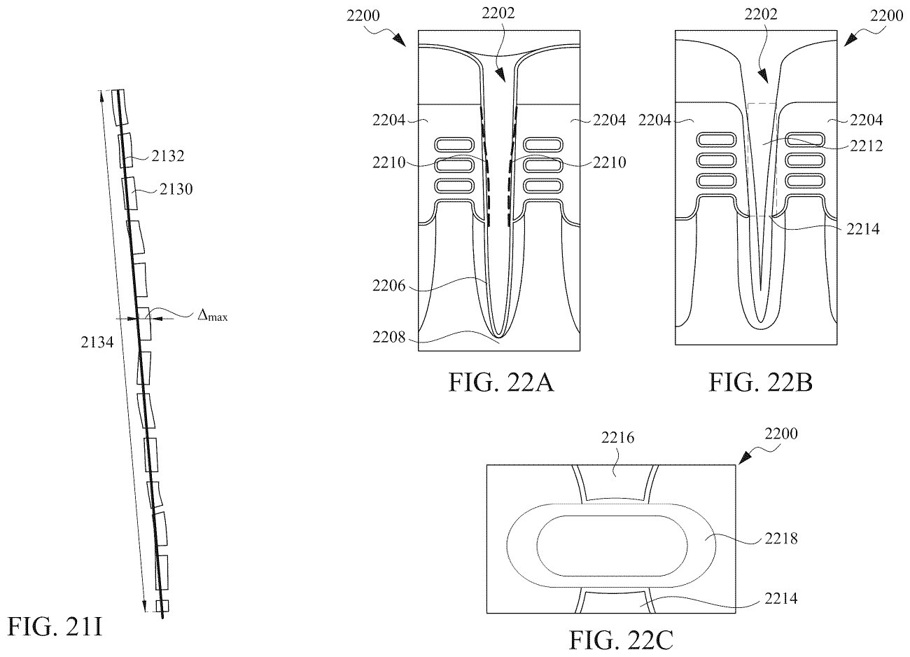

FIG. 22A is a diagram depicting a cross-sectional view of an example semiconductor structure 2200 after an opening 2202 has been formed through a gate structure 2204 and STI features 2206 and terminating before reaching a substrate 2208 during metal gate cutting operations, according to some embodiments. In this example, the opening 2202 has relatively smooth sidewalls 2210 with a roughness wherein a maximum deviation of the sidewalls 2210 from a slope line is less than 10 Å.

FIG. 22B is a diagram depicting a cross-sectional view of the example semiconductor structure 2200 after the opening 2202 has been filled with a dielectric material 2212, according to some embodiments. Because of the relatively smooth sidewalls 2210, the dielectric material 2212 may be deposited in the opening 2202 without the formation of a void (area without dielectric material) in the portion 2214 of the opening 2202 that separates the gate structure 2204. Eliminating voids in the opening can prevent metal drain to metal gate shorts.

FIG. 22C is a diagram depicting a plan view of the example semiconductor structure 2200 after the opening 2202 has been formed through a gate structure 2204. Shown are a first structure 2216 and a second structure 2218. Because the second structure 2218 has an oval-like shape with straight sides (e.g., a stadium-like shape) and lacks bowing in the sides to a more circular shape, the opening 2202 may be filled with a dielectric material without the formation of a void (area without dielectric material) in the portion 2214 of the opening 2202 that separates the gate structure 2204. Because the profile of the opening 2201 has a tapered profile instead of a bowing profile, metal drain to metal gate shorts may be eliminated.

In some aspects, the techniques described herein relate to a method including: providing a plurality of fins that extend vertically above a substrate and a contiguous gate structure that extends over the plurality of fins; forming an opening in the contiguous gate structure with a metal gate cut between a pair of fins, wherein forming the opening includes etching a partial opening to a current depth and performing an etching cycle including: depositing a protective layer on sidewalls of the partial opening; and extending, via etching, the partial opening a predetermined incremental depth below the current depth; and repeating the etching cycle for a plurality of cycles to achieve a desired gate cut length.

In some aspects, the techniques described herein relate to a method, wherein the plurality of cycles comprises at least 10 cycles.

In some aspects, the techniques described herein relate to a method, wherein forming the opening further includes generating the metal gate cut with a sidewall of the metal gate cut having a maximum delta distance (Δmax) of about 10 Å or less from a slope line along the sidewall of the metal gate cut.

In some aspects, the techniques described herein relate to a method, wherein forming the opening further includes generating the metal gate cut with a ratio of the maximum delta distance (Δmax) to the gate cut length of about 1 to about 100 or more.

In some aspects, the techniques described herein relate to a method, wherein forming the opening further includes generating the metal gate cut with a sidewall of the metal gate cut having an average delta distance (Δavg) of about 5 Å or less from a slope line along the gate cut length.

In some aspects, the techniques described herein relate to a method, wherein forming the opening further includes generating the metal gate cut with a ratio of the average delta distance (Δavg) to the gate cut length of about 1 to about 200 or more.

In some aspects, the techniques described herein relate to a method, wherein the predetermined incremental depth is between about 5 nanometers (nm) and about 25 nm.

In some aspects, the techniques described herein relate to a method, wherein the protective layer includes a silicon oxide (SiO₂) or a carbon nitride (CN).

In some aspects, the techniques described herein relate to a method, wherein the protective layer has a thickness of about 5 Å to about 50 Å.

In some aspects, the techniques described herein relate to a method, including depositing the protective layer in a plasma processing chamber using one or more of SiCl₄, HBr, O₂, CH₄, and N₂ as a process gas.

In some aspects, the techniques described herein relate to a method, wherein extending the partial opening includes performing plasma etching with process gases including one or more of CF₄, CH₃F, CHF₃, CH₄, Cl₂, C4F₆, BCl₃, SiCl₄, HBr, O₂, or N₂ supplied into a processing chamber.

In some aspects, the techniques described herein relate to a semiconductor structure including: a plurality of fins that extend vertically above a substrate, a first gate segment that extends over a first fin, a second gate segment that extends over a second fin; an opening that separates the first gate segment from the second gate segment, the opening having a gate cut length; the opening including a plurality of cut segments of a predetermined incremental depth along the gate cut length; and a dielectric material disposed in the opening that isolates the first gate segment from the second gate segment without a void in the dielectric material between the first gate segment and the second gate segment.

In some aspects, the techniques described herein relate to a semiconductor structure, wherein the plurality of cut segments comprises at least 10 cut segments.

In some aspects, the techniques described herein relate to a semiconductor structure, wherein the predetermined incremental depth is between about 5 nanometers (nm) and about 25 nm.

In some aspects, the techniques described herein relate to a semiconductor structure, wherein a sidewall of the opening includes a maximum delta distance (Δmax) of about 10 Å or less from a slope line for the sidewall along the gate cut length.

In some aspects, the techniques described herein relate to a semiconductor structure, wherein the opening includes a ratio of the maximum delta distance (Δmax) to the gate cut length of about 1 to about 100 or more.

In some aspects, the techniques described herein relate to a semiconductor structure, wherein a sidewall of the opening includes an average delta distance (Δavg) of about 5 Å or less from a slope line for the sidewall along the gate cut length.

In some aspects, the techniques described herein relate to a semiconductor structure, wherein the opening includes a ratio of the average delta distance (Δavg) to the gate cut length of about 1 to about 200 or more.

In some aspects, the techniques described herein relate to a semiconductor structure, wherein the first gate segment and the second gate segment include gate structures for a gate all around device.

In some aspects, the techniques described herein relate to a semiconductor structure, wherein the first gate segment and the second gate segment include gate structures for a FinFET device.

In some aspects, the techniques described herein relate to a semiconductor structure, wherein the opening is between a gate structure for an n-channel transistor and a gate structure for a p-channel transistor.

In some aspects, the techniques described herein relate to a semiconductor structure, wherein the opening is between a gate structure for a first n-channel transistor and a gate structure for a second n-channel transistor.

In some aspects, the techniques described herein relate to a semiconductor structure, wherein the opening is between a gate structure for a first p-channel transistor and a gate structure for a second p-channel transistor.

In some aspects, the techniques described herein relate to a method including: providing a plurality of fins that extend vertically above a substrate and a contiguous gate structure that extends over the plurality of fins; forming an opening in the contiguous gate structure with a metal gate cut between a pair of fins, wherein forming the opening includes etching a partial opening to a current depth and performing a plasma etching cycle including: depositing a protective layer on sidewalls of the partial opening in a plasma processing chamber; and extending the partial opening a predetermined incremental depth below the current depth by performing plasma etching; and repeating the plasma etching cycle for a plurality of cycles to achieve a desired gate cut length.

In some aspects, depositing the protective layer on sidewalls of the partial opening in a plasma processing chamber comprises depositing the protective layer on sidewalls of the partial opening in a plasma processing chamber using one or more of SiCl₄, HBr, O₂, CH₄, and N₂ as a process gas.

In some aspects, extending the partial opening the predetermined incremental depth below the current depth by performing plasma etching comprises extending the partial opening the predetermined incremental depth below the current depth by performing plasma etching using process gases including one or more of CF₄, CH₃F, CHF₃,CH₄, Cl₂, C₄F₆, BCl₃, SiCl₄, HBr, O₂, or N₂ supplied into the plasma processing chamber.

In some aspects, the techniques described herein relate to a method, wherein the plurality of cycles comprises at least 10 cycles.

In some aspects, the techniques described herein relate to a method, wherein the protective layer includes a silicon oxide (SiO₂) or a carbon nitride (CN).

In some aspects, the techniques described herein relate to a method, wherein the protective layer has a thickness of about 5 Å to about 50 Å.

In some aspects, the techniques described herein relate to a method, wherein the predetermined incremental depth is between about 5 nanometers (nm) and about 25 nm.

In some aspects, the techniques described herein relate to a method, wherein performing the plasma etching further includes performing plasma etching by flowing the process gases into the plasma processing chamber at a rate between about 5 sccm (standard cubic centimeters per minute) and about 1000 sccm; performing plasma etching using a bias voltage between about 0 volts and about 1000 volts, and with a power between about 50 watts and about 3000 watts; performing plasma etching at a temperature between about 50° C. and about 200° C.; and performing plasma etching with a pressure in the plasma processing chamber between about 3 mTorr and about 5 Torr.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A method comprising:
providing a plurality of fins that extend vertically above a substrate and a contiguous gate structure that extends over the plurality of fins;
forming an opening in the contiguous gate structure with a metal gate cut between a pair of fins, wherein forming the opening comprises etching a partial opening to a current depth and performing an etching cycle comprising:
depositing a protective layer on sidewalls of the partial opening; and
extending, via etching, the partial opening a predetermined incremental depth below the current depth; and
repeating the etching cycle for a plurality of cycles to achieve a desired gate cut length.

2. The method of claim 1, wherein forming the opening further comprises generating the metal gate cut with a sidewall of the metal gate cut having a maximum delta distance (Δₘₐₓ) of about 10 Å or less from a slope line along the sidewall of the metal gate cut.

3. The method of claim 1, wherein forming the opening further comprises generating the metal gate cut with a sidewall of the metal gate cut having an average delta distance (Δ_{avg}) of about 5 Å or less from a slope line along the gate cut length.

4. The method of claim 1, wherein the predetermined incremental depth is between about 5 nanometers (nm) and about 25 nm.

5. The method of claim 1, wherein the protective layer comprises a silicon oxide (SiO₂) or a carbon nitride (CN).

6. The method of claim 1, wherein the protective layer has a thickness of about 5 Å to about 50 Å.

7. The method of claim 1, comprising depositing the protective layer in a plasma processing chamber using one or more of SiCl₄, HBr, O₂, CH₄, and N₂ as a process gas.

8. The method of claim 1, wherein the plurality of cycles comprises at least 10 cycles.

9. A semiconductor structure comprising:
a plurality of fins that extend vertically above a substrate, a first gate segment that extends over a first fin, a second gate segment that extends over a second fin;
an opening that separates the first gate segment from the second gate segment, the opening having a gate cut length;
the opening comprising a plurality of cut segments of a predetermined incremental depth along the gate cut length; and
a dielectric material disposed in the opening that isolates the first gate segment from the second gate segment without a void in the dielectric material between the first gate segment and the second gate segment.

10. The semiconductor structure of claim 9, wherein the predetermined incremental depth is between about 5 nanometers (nm) and about 25 nm.

11. The semiconductor structure of claim 9, wherein a sidewall of the opening comprises a maximum delta distance (Δₘₐₓ) of about 10 Å or less from a slope line for the sidewall along the gate cut length.

12. The semiconductor structure of claim 11, wherein the opening comprises a ratio of the maximum delta distance (Δₘₐₓ) to the gate cut length of about 1 to about 100 or more.

13. The semiconductor structure of claim 9, wherein a sidewall of the opening comprises an average delta distance (Δ_{avg}) of about 5 Å or less from a slope line for the sidewall along the gate cut length.

14. The semiconductor structure of claim 13, wherein the opening comprises a ratio of the average delta distance (Δ_{avg}) to the gate cut length of about 1 to about 200 or more.

15. The semiconductor structure of claim 9, wherein the first gate segment and the second gate segment comprise gate structures for a gate all around device.

16. A method comprising:
providing a plurality of fins that extend vertically above a substrate and a contiguous gate structure that extends over the plurality of fins;
forming an opening in the contiguous gate structure with a metal gate cut between a pair of fins, wherein forming the opening comprises etching a partial opening to a current depth and performing a plasma etching cycle comprising:
depositing a protective layer on sidewalls of the partial opening in a plasma processing chamber; and
extending the partial opening a predetermined incremental depth below the current depth by performing plasma etching; and
repeating the plasma etching cycle for a plurality of cycles to achieve a desired gate cut length.

17. The method of claim 16, wherein depositing the protective layer on sidewalls of the partial opening in the plasma processing chamber comprises depositing the protective layer on sidewalls of the partial opening in the plasma processing chamber using one or more of SiCl₄, HBr, O₂, CH₄, and N₂ as a process gas.

18. The method of claim 16, wherein extending the partial opening the predetermined incremental depth below the current depth by performing plasma etching comprises extending the partial opening the predetermined incremental depth below the current depth by performing plasma etching using process gases including one or more of CF₄, CH₃F, CHF₃,CH₄, Cl₂, C₄F₆, BCl₃, SiCl₄, HBr, O₂, or N₂ supplied into the plasma processing chamber.

19. The method of claim 16, wherein the plurality of cycles comprises at least 10 cycles.

20. The method of claim 16, wherein performing the plasma etching further comprises:
flowing the process gases into the plasma processing chamber at a rate between about 5 sccm (standard cubic centimeters per minute) and about 1000 sccm;
performing plasma etching using a bias voltage between about 0 volts and about 1000 volts, and with a power between about 50 watts and about 3000 watts;
performing plasma etching at a temperature between about 50° C. and about 200° C.; and;
performing plasma etching with a pressure in the plasma processing chamber between about 3 mTorr and about 5 Torr.
